(19) United States
(12) Patent Application Publication
(10) Pub. No.: US 2012/0125765 A1
(43) Pub. Date: May 24, 2012

(54) PLASMA PROCESSING APPARATUS AND PRINTED WIRING BOARD MANUFACTURING METHOD

(75) Inventors: Tadahiro Ohmi, Sendai-shi (JP); Tetsuya Goto, Sendai-shi (JP); Takaaki Matsuoka, Tokyo (JP)

(73) Assignees: TOKYO ELECTRON LIMITED, Tokyo (JP); TOHOKU UNIVERSITY, Sendai-shi, Miyagi (JP)

(21) Appl. No.: 13/387,789

(22) PCT Filed: Jul. 16, 2010
(86) PCT No.: PCT/JP2010/062056

§ 371 Date: Feb. 6, 2012

(30) Foreign Application Priority Data
Jul. 30, 2009 (JP) 2009-177990

(51) Int. Cl. C23C 14/35

(52) U.S. Cl. 204/192.17; 204/298.16

(57) ABSTRACT

It is an object of the present invention to provide a wiring board plasma processing apparatus capable of improving throughput and achieving reduction in running cost while a sputtering process is employed in manufacturing a wiring board. The wiring board plasma processing apparatus of the present invention has, in a same plasma processing chamber, a surface processing portion provided with a plasma source and performing a pretreatment of a board to be processed, and a plurality of sputtering film forming portions forming a seed layer formed of a plurality of films.

### TECHNICAL FIELD

This invention relates to a plasma processing apparatus for manufacturing a wiring board and a manufacturing method thereof.

### BACKGROUND ART

In general, a wiring board is widely used as a printed wiring board adapted to mount an electronic device and so on to construct an electronic apparatus. With downsizing of the electronic apparatus and the like, high accuracy and high density are required for the printed wiring board. Normally, copper is used as a wiring material in the wiring board and is formed into a predetermined pattern by electrolytic plating. As a method of forming a feed layer in formation of a copper wiring by electrolytic plating, it is general that, after a wet process is used as a pretreatment, electroless copper plating is performed. Thereafter, electrolytic plating of copper is performed with an electroless plating layer used as a seed layer (feed layer).

However, electroless plating is disadvantageous in that variation in plating quality is difficult to suppress as compared to electrolytic plating, a large amount of chemicals are required, and the number of necessary steps is large. Therefore, as a process to replace electroless plating, consideration is made of a method of forming copper for the seed layer by a sputtering process. Copper formed by sputtering has difficulty in securing adhesion with an electrically-insulating layer of a printed board, i.e., a thermosetting resin. However, it is proposed to improve adhesion by forming copper nitride by sputtering as an initial layer of the seed layer (Patent Document 1 and Patent Document 2). Even if copper nitride is formed as the initial layer of the seed layer as described in Patent Documents 1 and 2, no copper seed layer having adhesion which endures practical use has been obtained.

On the other hand, Patent Document 3 has proposed that a surface of the thermosetting resin is nitrided to improve adhesion between the copper seed layer and the surface of the thermosetting resin.

### PRIOR ART DOCUMENTS

### Patent Documents

Patent Document 1: JP-A-2003-218516
Patent Document 2: JP-A-H10-133597
Patent Document 3: PCT/JP2009/59838

### SUMMARY OF THE INVENTION

### Problem to be Solved by the Invention

Patent Document 3 discloses a method of continuously performing, by using only a sputtering apparatus, cleaning of a surface of a substrate or board, nitridation of a surface of a thermosetting resin, formation of a copper nitride film as an initial layer of a seed layer, and sputtering film formation of copper as the seed layer. However, when only the magnetron sputtering apparatus is used to perform cleaning of the surface of the board, nitridation of the surface of the thermosetting resin, formation of the copper nitride film as the initial layer of the seed layer, and sputtering film formation of copper as the seed layer, there is a problem that throughput is reduced.

Further, in the sputtering process, the board is put in a vacuum device to be processed. Therefore, after the board to be processed is put in the device, a time for vacuuming is required. Furthermore, it is generally necessary to form a wiring on both surfaces of a printed board. Therefore, a processing time inevitably becomes long. Accordingly, it is difficult to improve throughput. In addition, there is a problem that the sputtering apparatus is low in efficiency of use of a target to thereby increase a running cost.

It is an object of the present invention to provide a manufacturing device and a manufacturing method of a wiring board capable of improving throughput and reducing a running cost while a sputtering process is used in manufacture of the wiring board.

According to a first aspect of this invention, there is provided a plasma processing apparatus characterized by comprising a processing container whose length from one end to the other end is not less than three times a length of a board to be processed and which is reducible in pressure; a transfer mechanism transferring the board from the one end to the other end of the processing container; a surface processing portion having a plasma source; a first magnetron-sputtering film-forming portion; and a second magnetron-sputtering film-forming portion; the surface processing portion and the first and the second magnetron-sputtering film-forming portions being disposed in the processing container along a direction from the one end toward the other end of the processing container.

According to a second aspect of this invention, there is provided the plasma processing apparatus, characterized in that the surface processing portion has the plasma source of a parallel-plate type.

According to a third aspect of this invention, there is provided the plasma processing apparatus according to the second aspect, characterized in that the parallel-plate type plasma source has one electrode arranged on the side of one surface of the board which is transferred by the transfer mechanism and the other electrode arranged on the side of the other surface of the board.

According to a fourth aspect of this invention, there is provided the plasma processing apparatus, characterized in that the surface processing portion further comprises a mechanism transferring the board in a direction perpendicular to a surface of the board.

According to a fifth aspect of this invention, there is provided the plasma processing apparatus characterized in that the first magnetron-sputtering film-forming portion and the second magnetron-sputtering film-forming portion are adapted to form films different in composition from each other.

According to a sixth aspect of this invention, there is provided the plasma processing apparatus characterized in that the first magnetron-sputtering film-forming portion and the second magnetron-sputtering film-forming portion are adapted to form films same in composition as each other.

According to a seventh aspect of this invention, there is provided the plasma processing apparatus characterized in that each of the first magnetron-sputtering film-forming portion and the second magnetron-sputtering film-forming portion has at least one magnetron sputtering source on the side of one surface of the board transferred by the transfer mechanism and at least one magnetron sputtering source on the side of the other surface of the board.

According to an eighth aspect of this invention, there is provided the plasma processing apparatus according to the seventh aspect, characterized in that each of the first magnetron-sputtering film-forming portion and the second magnetron-sputtering film-forming portion has a rotating magnet type magnetron sputtering source.

According to a ninth aspect of this invention, there is provided the plasma processing apparatus characterized in that the transfer mechanism simultaneously delivers a plurality of the boards.

According to a tenth aspect of this invention, there is provided the plasma processing apparatus characterized in that the transfer mechanism simultaneously delivers a plurality of the boards in a transfer direction and in a direction perpendicular to the transfer direction.

According to an eleventh aspect of this invention, there is provided a plasma processing apparatus characterized by comprising: a processing container reducible in pressure; a first plasma processing portion having a plasma source arranged in the processing container and modifying a surface of a board to be processed, by irradiating the board with a plasma; and a second plasma processing portion having a plurality of magnetron sputtering sources arranged in the processing container and depositing a thin film by magnetron sputtering, the plasma source of the first plasma processing portion being disposed so as to allow plasma irradiation on both surfaces of the board without requiring an operation of reversing the board, the magnetron sputtering sources being disposed to face the both surfaces of the board, respectively, so as to allow formation of thin films on the both surfaces of the board without requiring an operation of reversing the board.

According to a twelfth aspect of this invention, there is provided the plasma processing apparatus characterized in that the first plasma processing portion includes a first plasma excitation electrode and a second plasma excitation electrode which are arranged to face a first surface of the board and a second surface opposite to the first surface, respectively, and to be substantially in parallel to the board and each of which has a size substantially equal to that of the board.

According to a thirteenth aspect of this invention, there is provided the plasma processing apparatus characterized in that: the first plasma processing portion has a mechanism transferring the board in a direction perpendicular to the first surface, plasma processing of the first surface of the board being performed by bringing the second surface into contact with the second plasma excitation electrode and applying an electric power to the second electrode only or to both of the first and the second electrodes to thereby generate a plasma between the first surface and the first electrode so as to perform plasma processing of the first surface, plasma processing of the second surface of the board being performed by bringing the first surface into contact with the first plasma excitation electrode and applying an electric power to the first electrode only or to both of the second and the first electrodes to thereby generate a plasma between the second surface and the second electrode so as to perform plasma processing of the second surface.

According to a fourteenth aspect of this invention, there is provided the plasma processing apparatus characterized by comprising a third plasma processing portion arranged in the processing container to be adjacent to the second plasma processing portion and having a plurality of magnetron sputtering sources, the magnetron sputtering sources being disposed to face the both surfaces of the board, respectively, so as to form a thin film on each of the both surfaces of the board without requiring an operation of reversing the board.

According to a fifteenth aspect of this invention, there is provided the plasma processing apparatus characterized in that each of the magnetron sputtering sources is a rotating magnet sputtering.

According to a sixteenth aspect of this invention, there is provided a printed wiring board manufacturing method using the plasma processing apparatus according to any one of the above-mentioned aspects, characterized in that: the board is a board to be formed with a wiring pattern on a thermosetting resin; the method comprising a first plasma processing step of performing, in the first plasma processing portion, plasma excitation by a gas containing at least hydrogen and irradiating the board with active hydrogen to remove an oxide film on at least a part of each of the surfaces of the board; and a second plasma processing step of performing, in the first plasma processing portion, plasma excitation by a gas containing at least nitrogen and irradiating the board with active nitrogen to nitride at least a part of each of the surfaces of the board.

According to a seventeenth aspect of this invention, there is provided a printed wiring board manufacturing method using the plasma processing apparatus according to any one of the above-mentioned aspects, characterized in that: the board is a board to be formed with a wiring pattern on a thermosetting resin; the method comprising a plasma processing step of performing, in the first plasma processing portion, plasma excitation by a gas containing at least hydrogen and nitrogen and irradiating the board with active hydrogen and NH radicals to remove an oxide film on at least a part of each of the surfaces of the board and to simultaneously nitride at least a part of each of the surfaces of the board.

According to an eighteenth aspect of this invention, there is provided a printed wiring board manufacturing method using the plasma processing apparatus according to any one of the above-mentioned aspects, characterized in that: the board is a board to be formed with a wiring pattern on a thermosetting resin; the method comprising the steps of: performing plasma processing of each of the surfaces of the board in the first plasma processing portion; and forming a conductive layer containing at least one of copper nitride, chromium, aluminum, titanium, and tantalum by the magnetron sputtering sources in the second plasma processing portion.

According to a nineteenth aspect of this invention, there is provided a printed wiring board manufacturing method using the plasma processing apparatus according to any one of the above-mentioned aspects, characterized in that: the board is a board to be formed with a wiring pattern on a thermosetting resin; the method comprising the steps of: performing plasma processing of each of the surfaces of the board in the first plasma processing portion; forming a first conductive layer by the magnetron sputtering sources in the second plasma processing portion; and forming a second conductive layer on the first conductive layer by the magnetron sputtering sources in the third plasma processing portion.

### Effect of the Invention

According to the present invention, in formation of a wiring on a board by sputtering, it is possible to achieve improvement of throughput and reduction in running cost by separately arranging a surface processing portion and a sputtering film forming portion in a transfer direction of the board. Further, it is possible to further improve throughput and further reduce a running cost by simultaneously performing surface processing and sputtering film formation on both of front and back surfaces of the board.

### BRIEF DESCRIPTION OF THE DRAWING

FIG. 1 is a sectional view for describing a structure of a first embodiment of the present invention.

FIG. 2 is a sectional view showing processing steps in a surface processing portion of an apparatus in FIG. 1.

FIG. 3 shows sectional views for describing a structure of a second embodiment of the present invention, the upper view being a sectional view as seen from a side surface of the apparatus, the lower view being a sectional view as seen from an upper surface of the apparatus.

FIG. 4 is a partial sectional view schematically showing a printed board manufactured using a plasma processing apparatus of the present invention.

### MODE FOR EMBODYING THE INVENTION

Hereinbelow, embodiments of the present invention will be described using the drawings.

### First Embodiment

A first embodiment of the present invention will be described in detail with reference to the drawings.

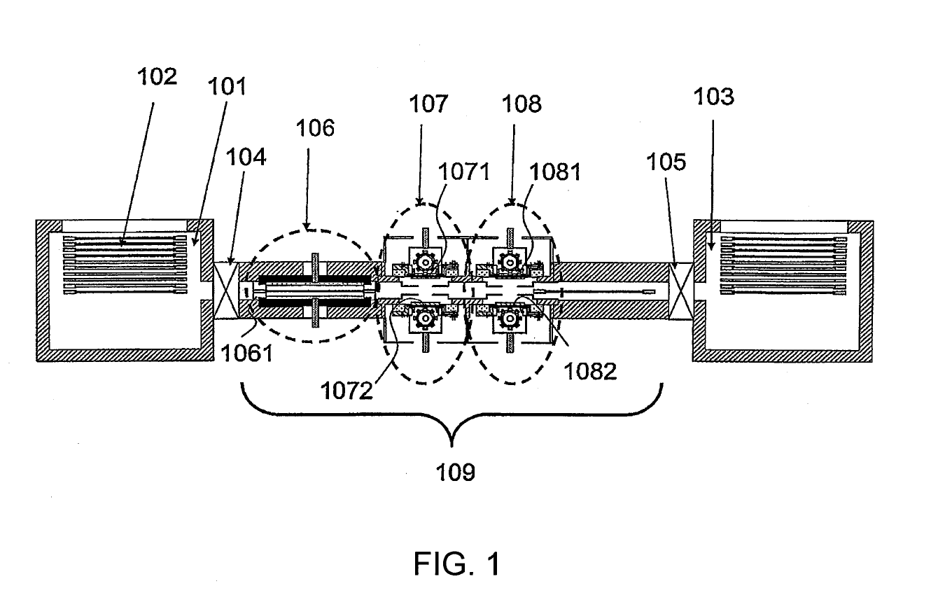

FIG. 1 is a sectional view for describing a structure of a plasma processing apparatus according to the first embodiment of the present invention. Herein, the plasma processing apparatus is used for forming a wiring material on a printed board. In FIG. 1, a reference numeral 101 represents a board loading chamber, 102, a printed board (board to be processed or board), 103, a board unloading chamber, 109, a plasma processing chamber, 104, a gate valve for separating the plasma processing chamber 109 and the board loading chamber 101, and 105, a gate valve for separating the plasma processing chamber 109 and the board unloading chamber 103.

106 represents a surface processing portion which is a unit provided with a plasma source having a parallel plate electrode and adapted to perform plasma cleaning and plasma nitriding of a surface of the board by exciting a plasma in the plasma source. 107 and 108 represent magnetron-sputtering film-forming portions. 107 represents a first magnetron-sputtering film-forming portion provided with two sets of magnetron sputtering sources arranged at upper and lower positions, respectively, for forming copper nitride. 108 represents a second magnetron-sputtering film-forming portion provided with two sets of magnetron sputtering sources arranged at upper and lower positions, respectively, for forming copper. The plasma processing chamber 109 is provided with a transfer mechanism (not shown in the figure) for transferring the board 102 from the gate valve 104 to the gate valve 105 through the surface processing portion 106 and the first and the second magnetron-sputtering film-forming portions 107 and 108. As the transfer mechanism, the embodiment uses a transfer mechanism capable of transferring the board not only in the above-mentioned one direction but also in a reverse direction (returning direction) back along the way. As the transfer mechanism of the type, use may be made of a transfer mechanism used in an inline type plasma processing apparatus.

In FIG. 1, the plasma processing chamber 109 is used in which a length from one end defined by the gate valve 104 to the other end defined by the gate valve 105 is not shorter than three times a length of the board 102. Specifically, the plasma processing chamber 109 has a length determined by the surface processing portion 106 having a length substantially equal to the length of the board 102 in its transfer direction, the first and the second magnetron-sputtering film-forming portions 107 and 108 having a total length substantially equal to the length of the board 102 in the transfer direction, and an unloading space having a length equal to or greater than the length of the board 102 and adapted to hold the board 102 after processed in order to unload it to the unloading chamber 103.

In the plasma processing apparatus, all of the board loading chamber 101, the plasma processing chamber 109, and the board unloading chamber 103 can be reduced in pressure. The board loading chamber 101 and the board unloading chamber 103 are kept at an atmospheric pressure when the board is loaded and unloaded. The plasma processing chamber 109 is basically kept in a reduced-pressure state except during maintenance. The board 102 is set in the board loading chamber 101. After the board loading chamber 101 is reduced in pressure, the gate valve 104 is opened and the board 102 is introduced into the surface processing portion 106 of the plasma processing chamber 109 by a robot (not shown in the figure). The surface processing portion 106 is provided with the transfer mechanism for transferring the introduced board 102 not only in a direction toward the magnetron-sputtering film-forming portion 107 but also in a reverse direction and further in a direction perpendicular to the transfer direction, as symbolically shown by a reference numeral 1061.

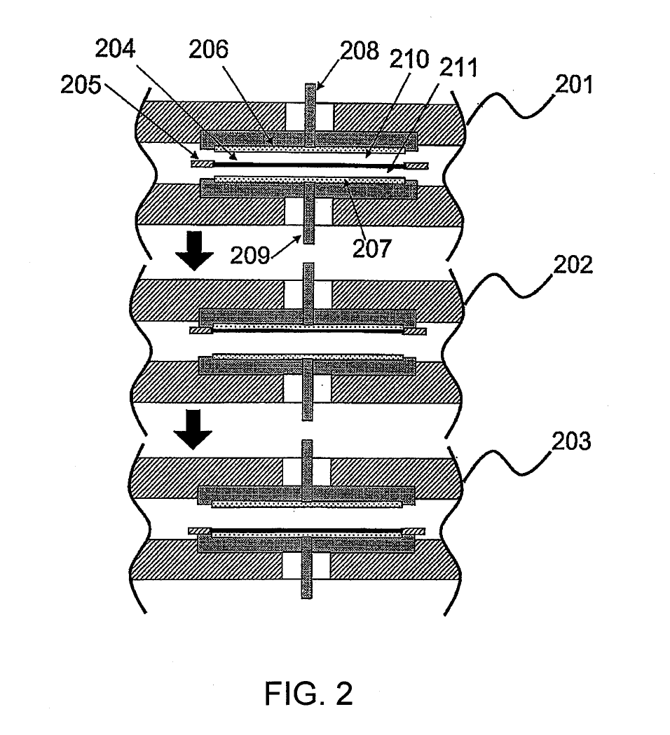

A structure of the plasma source disposed in the surface processing portion 106 and a plasma processing method using the plasma source will be described in detail using FIG. 2. FIG. 2 is a view showing the plasma source in the surface processing portion 106 more in detail and shows processing steps 201, 202, and 203 of plasma processing. 204 represents a board to be processed, 206, a first plasma excitation electrode, 207, a second plasma excitation electrode, 208, a first feed line for supplying an electric power to the first plasma excitation electrode, and 209, a second feed line for supplying an electric power to the second plasma excitation electrode.

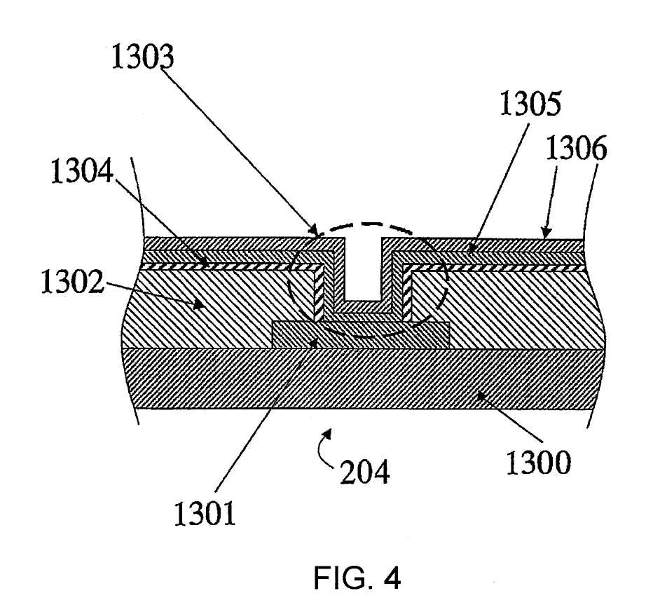

The board 204 shown in FIG. 2 is a wiring board for a printed board of a laminated structure and one surface of the board is partly shown in FIG. 4. The wiring board shown in FIG. 4 has, for example, an insulator base 1300 formed of a thermosetting resin, an internal layer Cu wiring 1301 formed on the base 1300, and an insulating resin 1302 formed so as to cover the internal layer Cu wiring 1301 and the base 1300. At a part of the insulating resin 1302, a via hole 1303 is formed to expose the internal layer Cu wiring 1301. Although omitted in the figure, a similar wiring structure is formed also on the opposite surface. The wiring board is introduced into the surface processing portion 106 with the internal layer Cu wiring 1301 exposed.

It is noted here that the board 204 is a rectangular board having a size of 40 cm×50 cm and its periphery is fixed by jigs 205 for supporting the board 204. The board 204 is transferred together with the jigs 205 by the transfer mechanism after it is loaded into the board loading chamber (102 in FIG. 1) and until it is unloaded from the board unloading chamber (103 in FIG. 1). The jigs 205 are used mainly for the purpose of stably transferring the board without bending. An area of the board 204, which is supported by the jigs 205, is desirably as small as possible in order to increase an effective area of the board 204.

The plasma excitation electrodes 206 and 207 are disposed to face upper and lower opposite surfaces of the board, respectively. The surface of the board 204 on the side of the first plasma excitation electrode 206 is defined as a first surface and the opposite surface is defined as a second surface. 210 represents a space between the first surface of the board and the first plasma excitation electrode 206 and 211 represents a space between the second surface of the board and the second plasma excitation electrode 207.

The processing step 201 shows a state where the board 204 is delivered from the board loading chamber 101 to the surface processing portion 106 and delivered to a position between the plasma excitation electrodes 206 and 207. The first plasma excitation electrode 206 and the second plasma excitation electrode 207, each of which has a size substantially equal to that of the board 204, are arranged to face the first and the second surfaces of the board, respectively, and disposed in parallel to the board. In this state, the board 204 is held exactly in the middle between the first plasma excitation electrode 206 and the second plasma excitation electrode 207.

As described above, the board 204 has the transfer mechanism 1061 (FIG. 1) for moving the board together with the jigs 205 in the direction perpendicular to the board, i.e., in a direction perpendicular to the surfaces of the plasma excitation electrodes 206 and 207.

Using the transfer mechanism 1061, the first surface and the second surface of the board 204 are successively subjected to plasma cleaning and plasma nitridation. First, in order to process the second surface of the board 204, the first surface is brought into contact with the first plasma excitation electrode 206 as shown in the processing step 202. In this state, argon and hydrogen are introduced into the plasma processing chamber at a flow rate ratio of 9:1 and a pressure is set at 50 mTorr. Herein, under the condition that the first plasma excitation electrode 206 is supplied with a RF power of 13.56 MHz at a power density of 0.2 W/cm² so that ion irradiation to the second surface of the board 204 is equal to about 40 eV, a plasma is excited and plasma cleaning is performed for 8 seconds.

The above-mentioned step mainly removes an oxide film of Cu on an exposed surface of the internal layer Cu wiring 1301 at the bottom of the via hole 1303 (FIG. 4). When plasma excitation is performed by argon only, there is an effect of removing the oxide film. However, by introducing hydrogen in addition, the removing effect is increased by utilizing a reduction effect with hydrogen radicals. Further, for the purpose of increasing a cleaning effect by further increasing the plasma density, a RF power may simultaneously be applied to the second plasma excitation electrode 207.

Next, argon and nitrogen are introduced into the plasma processing chamber (109 in FIG. 1) at a flow rate ratio of 7.5:2.5 and a pressure is set at 100 mTorr. The first plasma excitation electrode 206 is applied with a RF power of 13.56 MHz at a power density of 0.3 W/cm² to excite a plasma and generate active nitrogen radicals. Thus, a surface of the resin (1302 in FIG. 4) on the second surface of the board 204 is nitrided for 8 seconds. As mentioned above, plasma cleaning of the second surface of the board 204 and nitridation of the resin surface are performed. Also with respect to the nitridation process, an electric power may be applied to the second plasma excitation electrode 207 in order to further increase the effect. As a result, on the surface of the resin layer 1302 on the second surface of the board 204, a nitride resin layer 1304 is formed as shown in FIG. 4.

In order to increase the plasma density so as to enhance the effects of the plasma cleaning and the plasma nitridation, the RF power is preferably used. However, even when a DC power is used in view of a cost of a power source and the like, an equivalent effect is obtained if processing is performed for a longer time.

Next, in order to process the first surface of the board 204, the second surface of the board 204 is brought into contact with the second plasma excitation electrode 207 as shown in the processing step 203. Thereafter, the above-described process is performed by applying electric powers to the first and the second plasma excitation electrodes 206 and 207 in the manner such that a first plasma excitation power and a second plasma excitation power are exchanged. Thus, plasma cleaning and plasma nitridation of the first surface of the board 204 are finished. Thereafter, the board 204 is again returned to the middle between the plasma excitation electrodes 206 and 207 as in the processing step 201.

It is noted here that, as the plasma processing method, when an increase in throughput is desired, a RF power or a DC power may simultaneously be applied to both of the plasma excitation electrodes in a state where the board is located in the middle between the plasma excitation electrodes. For example, the second plasma excitation electrode 207 may be connected to ground and the first plasma excitation electrode 206 is applied with an electric power, thereby exciting a capacitively-coupled plasma. However, in this case, in order to obtain an effect equivalent to that of the processing method of moving the board 204 in the direction perpendicular to the board, a high plasma excitation power is required because the board 204 is distant from each of the plasma excitation electrodes 206 and 207.

When RF plasma discharge is carried out, a matching circuit and a blocking capacitor which are not shown in the figure are disposed at an end of each of the feed lines 208 and 209. By the blocking capacitor, the feed line and the plasma excitation electrode are galvanically isolated. Therefore, a switch for connecting each of the first and the second plasma excitation electrodes 206 and 207 to ground is preferably arranged at a position of each of the feed lines.

In any event, since the first plasma excitation electrode 206 and the second plasma excitation electrode 207, each of which has a size substantially equal to that of the board 204, are arranged to face the first and the second surfaces of the board, respectively, and disposed in parallel to the board 204, it is possible to perform plasma processing on both surfaces of the board 204 without requiring an operation of reversing the board 204.

Next, using FIG. 1 again, a process of forming a copper nitride film and a copper film on the board 102 (204) will be described. In the example illustrated in the figure, in order to form these films, there are provided the first magnetron-sputtering film-forming portion 107 (for forming the copper nitride film) provided with two sets of magnetron sputtering sources arranged at upper and lower positions, respectively, and the second magnetron-sputtering film-forming portion 108 (for forming the copper film) provided with two sets of magnetron sputtering sources arranged at upper and lower positions, respectively. The first magnetron-sputtering film-forming portion 107 is disposed downstream of the surface processing portion 106 along the transfer direction (left-to-right direction in FIG. 1) of the board. Further downstream thereof, the second magnetron-sputtering film-forming portion 108 is disposed. As a sputtering method of the sputtering sources of the magnetron-sputtering film-forming portions 107 and 108, use may be made of a normal magnetron sputtering method in which a stationary magnet is arranged on a rear surface of a target. However, it is preferable to use a rotating magnet sputtering method (details are disclosed in PCT International Publication WO2007/043476). By using the rotating magnet sputtering method, it is possible to improve a film forming rate and to reduce a target exchanging frequency due to a high efficiency of use of the target. Therefore, throughput can be increased and a running cost can be kept low.

Accordingly, the figure shows the example in which the sputtering apparatus of the rotating magnet sputtering method is used. In the first magnetron-sputtering film-forming portion 107, rectangular copper targets 1071 and 1072 are disposed in the plasma processing chamber 109 to face each other. The board is transferred through a middle portion between the both targets faced to each other, thereby performing film formation of copper nitride.

In the example illustrated in the figure, argon and nitrogen are introduced into the plasma processing chamber at a flow rate ratio of 97.5:2.5 and a pressure is set at 5 mTorr. A RF power of 13.56 MHz is applied to the targets at a power density of 4 W/cm² and a DC voltage of the targets is set at −340V to excite a plasma. Then, the board is transferred through the magnetron-sputtering film-forming portion 107 at a rate of 1 cm/s from left to right in FIG. 1. Thus, copper nitride (1305 in FIG. 4) having a film thickness of 20 nm is formed on each of the first and the second surfaces of the board.

Next, the step of copper film formation will be described. In FIG. 1, the second magnetron-sputtering film-forming portion 108 for film formation of copper is positioned adjacent to the first magnetron-sputtering film-forming portion 107 and downstream in the transfer direction of the board. Herein, like in the case of film formation of copper nitride, the rotating magnet sputtering method is employed. Also in the second magnetron-sputtering film-forming portion 108, rectangular copper targets 1081 and 1082 are disposed in the plasma processing chamber to face each other.

Therefore, if copper nitride is desired to be deposited thick, feeding to the second magnetron-sputtering film-forming portion 108 is similarly performed simultaneously with feeding to the first magnetron-sputtering film-forming portion 107. In the present embodiment, during feeding to the first magnetron-sputtering film-forming portion 107, feeding to the second magnetron-sputtering film-forming portion 108 is stopped.

In the process of copper film formation, the board is returned upstream of the second magnetron-sputtering film-forming portion 108. Then, feeding to the first magnetron-sputtering film-forming portion 107 is stopped and feeding to the second magnetron-sputtering film-forming portion 108 is started. The board is transferred through a middle portion between the both targets faced to each other, thereby performing copper film formation. In the example, argon is introduced into the plasma processing chamber and a pressure is set at 5 mTorr. A RF power of 13.56 MHz is applied to the targets at a power density of 4 W/cm² and a DC voltage of each of the targets 1081 and 1082 is set at −340V to excite a plasma. Then, the board is transferred through a target region at a rate of 2 mm/s. Thus, a copper seed film (1306 in FIG. 4) having a film thickness of 100 nm is formed. If a greater film thickness of copper is desired, the board is moved back upstream of the first magnetron-sputtering film-forming portion 107. Feeding to the first magnetron-sputtering film-forming portion 107 is performed in the manner similar to that to the second magnetron-sputtering film-forming portion 108. Argon is introduced into the plasma processing chamber. Then, sputtering film formation of copper is consecutively performed at the first magnetron-sputtering film-forming portion 107 and the second magnetron-sputtering film-forming portion 108.

After copper thin film formation is completed, the gate valve 105 is opened and the board is delivered to the board unloading chamber 103 to unload the board. Referring to FIG. 4, after the above-mentioned step, by electrolytic plating using the copper thin film 1306 as a seed layer, film formation of copper (not shown in the figure) is performed to a thickness about 25 μm on each of the first surface and the second surface of the board. Thereafter, unnecessary parts of the copper electrolytic plating layer, the underlying copper seed layer 1306, and the underlying copper nitride film 1305 are removed by wet etching. Thus, a desired wiring pattern is formed.

In the foregoing, formation of the copper seed layer according to the first embodiment of the present invention has been described. In the present embodiment, copper nitride is formed in the copper nitride forming step by exciting a plasma with argon and nitrogen gases and performing reactive-sputtering of the copper targets 1071 and 1072. Instead, copper nitride may be formed by argon plasma sputtering using copper nitride targets. In this case, simultaneously with feeding to the first magnetron-sputtering film-forming portion 107, feeding to the second magnetron-sputtering film-forming portion 108 is performed. Argon is introduced into the plasma processing chamber and film formation of copper can be performed subsequent to film formation of copper nitride. Alternatively, subsequent thereto, the board may be transferred in a reverse direction to be returned upstream of the second magnetron-sputtering film-forming portion 108. Then, while feeding to the first magnetron-sputtering film-forming portion 107 is stopped and feeding to the second magnetron-sputtering film-forming portion 108 is performed, the board is transferred in the forward direction to form a thicker copper film.

Without being limited to copper nitride, use may be made of a target of chromium, aluminum, titanium, tantalum, or the like, which assures adhesion with a resin. In this case, a plasma of argon only is generated. Therefore, a process similar to the above-mentioned case of the copper nitride target can be carried out.

In the example illustrated in the figure, description has been made about the case where the films (copper nitride film 1305 and copper seed film 1306) different in composition from each other are formed in the first and the second magnetron-sputtering film-forming portions 107 and 108, respectively. However, films having the same composition may be formed in the first and the second magnetron-sputtering film-forming portions 107 and 108.

### Second Embodiment

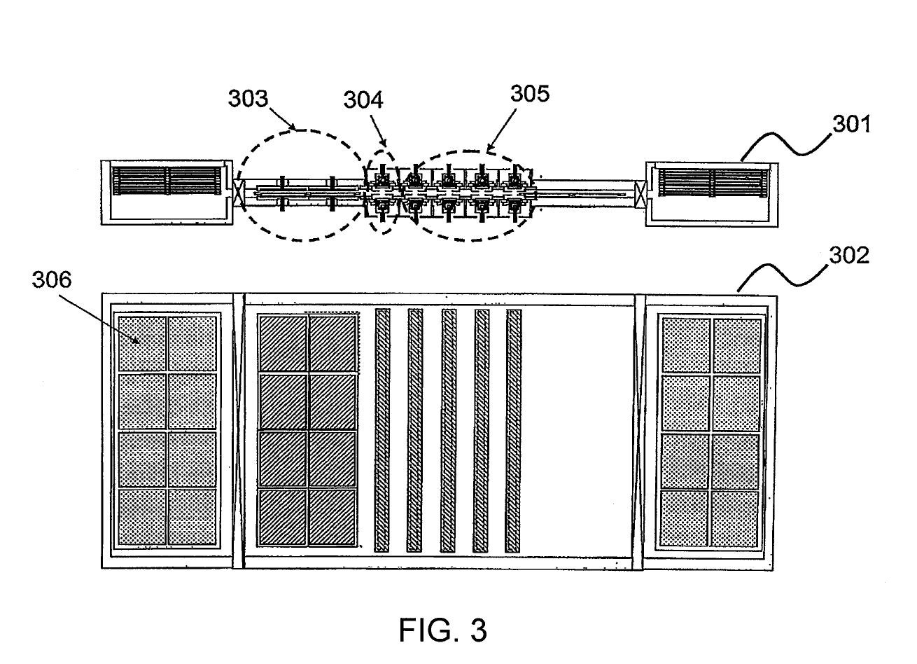

A second embodiment of the present invention will be described in detail with reference to FIG. 3. It is noted here that description about those parts overlapping with the first embodiment will be omitted. FIG. 3 is a view for describing a structure of the second embodiment of the plasma processing apparatus for forming a wiring material on a printed board. A reference numeral 301 represents a sectional view as seen from a side surface of the apparatus and 302 represents a sectional view as seen from an upper surface of the apparatus. 303 represents a board processing portion provided with plasma sources for performing plasma cleaning and nitriding of a resin surface of a board to be processed, 304, a first sputtering film forming portion having rotating magnet sputtering sources for forming copper nitride, and 305, a second sputtering film forming portion having rotating magnet sputtering sources for forming copper. 306 represents the board having a rectangular shape of 40 cm×50 cm. The boards 306 arranged two in its transfer direction (left-to-right direction in the figure) and four in a direction perpendicular to the transfer direction. The boards 306, eight in total, can be simultaneously delivered by jigs arranged around the boards. By providing a function of simultaneously delivering eight boards as one set, it is possible to increase the number of boards to be processed at one time.

The board processing portion 303 has the following structure. Specifically, two sets of plasma sources having a structure similar to that of the parallel-plate-type plasma source 106 described in connection with FIGS. 1 and 2 are arranged in a traveling direction of the board. Each electrode has a width approximately equal to that of the board and a length (length perpendicular to the transfer direction of the board) greater than a total length of the four boards. This structure enables simultaneous processing of the eight boards.

The first sputtering film forming portion 304 for forming copper nitride has a structure in which the rotating magnet sputtering sources are arranged along the transfer direction of the board, one on the side of a first surface of the board and another on the side of a second surface thereof. Further, the second sputtering film forming portion 305 for forming a copper thin film has a structure in which the rotating magnet sputtering sources are mounted up and down along the transfer direction of the board, eight in total, including four on the first surface of the board and four on the second surface thereof. A length (length perpendicular to the transfer direction of the board) of each of the rotating magnet sputtering sources of the first and the second sputtering film forming portions 304 and 305 is greater than a total length of the four boards. First, while feeding to the first sputtering film forming portion 304 is performed and feeding to the second sputtering film forming portion 305 is stopped, a plasma is excited by a nitrogen gas and an argon gas to perform reactive sputtering. Specifically, argon and nitrogen are introduced into the plasma processing chamber at a flow rate ratio of 97.5:2.5 and a pressure is set at 5 mTorr. A RF power of 13.56 MHz is applied at a power density of 4 W/cm² to copper targets of the first sputtering film forming portion 304 and a DC voltage of the targets is set at −340V to excite a plasma. Then, the board is transferred through the first magnetron-sputtering film-forming portion 304 at a rate of 1 cm/s from left to right in the figure. Thus, copper nitride having a film thickness of 20 nm is formed on a surface of each of the first and the second surfaces of the board. Next, by reversing the transfer mechanism, the board is returned upstream of the second sputtering film forming portion 305. Feeding to the first sputtering film forming portion 304 is stopped while feeding to the second sputtering film forming portion 305 is started. Then, a plasma is excited by an argon gas to perform copper sputtering. Conditions for feeding and sputtering are similar to those in the first embodiment. In the example illustrated in the figure, as a result of arranging the rotating magnet sputtering sources, eight in total, in the second sputtering film forming portion 305, a film forming rate of the copper thin film is improved so that throughput is improved

In the foregoing, the wiring board manufacturing device and the manufacturing method thereof have been shown in connection with the embodiments. However, the gas pressure, the gas flow rate ratio, the time, and the like in the surface processing conditions and the sputtering conditions are not limited to those in the above-described examples. Further, the ion irradiation step by an Ar gas or an Ar/H₂ gas plasma in the plasma cleaning is performed before the surface nitriding step of the resin layer but may be performed after surface nitriding and before the copper nitride forming step. Furthermore, plasma irradiation may be performed using a gas comprising an Ar/H₂ gas and a N₂ gas added thereto or a mixed gas of an Ar gas and an ammonia gas added thereto, instead of the Ar/H₂ gas plasma so that the ion irradiation step and the resin layer surface nitriding step mentioned above may simultaneously be performed.

In the embodiment illustrated in FIG. 1, the transfer mechanism for transferring the board in one direction and in the reverse direction is used as the transfer mechanism. Alternatively, a transfer mechanism for transferring the board in only one direction may be used.

### INDUSTRIAL APPLICABILITY

With the plasma processing apparatus according to the present invention, in formation of a wiring for printed board formation, the electroless plating process using a large amount of chemicals and having difficulty in reduction of a manufacturing cost can be replaced with a dry process using sputtering at a low cost and high throughput.

### DESCRIPTION OF REFERENCE NUMERALS

101 board loading chamber
102, 204, 306 board to be processed, for wiring board
103 board unloading chamber
104, 105 gate valve
106 surface processing portion
107, 108 magnetron-sputtering film-forming portion
109 plasma processing chamber

What is claimed is:

1. A plasma processing apparatus comprising a processing container whose length from one end to the other end is not less than three times a length of a board to be processed and which is reducible in pressure; a transfer mechanism transferring the board from the one end to the other end of the processing container; a surface processing portion having a plasma source; a first magnetron-sputtering film-forming portion; and a second magnetron-sputtering film-forming portion; the surface processing portion and the first and the second magnetron-sputtering film-forming portions being disposed in the processing container along a direction from the one end toward the other end of the processing container.

2. The plasma processing apparatus as claimed in claim 1, wherein the surface processing portion has the plasma source of a parallel-plate type.

3. The plasma processing apparatus as claimed in claim 2, wherein the parallel-plate type plasma source has one electrode arranged on the side of one surface of the board which is transferred by the transfer mechanism and the other electrode arranged on the side of the other surface of the board.

4. The plasma processing apparatus as claimed in claim 1, wherein the surface processing portion further comprises a mechanism transferring the board in a direction perpendicular to a surface of the board.

5. The plasma processing apparatus as claimed in claim 1, wherein the first magnetron-sputtering film-forming portion and the second magnetron-sputtering film-forming portion are adapted to form films different in composition from each other.

6. The plasma processing apparatus as claimed in claim 1, wherein the first magnetron-sputtering film-forming portion and the second magnetron-sputtering film-forming portion are adapted to form films same in composition as each other.

7. The plasma processing apparatus as claimed in claim 1, wherein each of the first magnetron-sputtering film-forming portion and the second magnetron-sputtering film-forming portion has at least one magnetron sputtering source on the side of one surface of the board transferred by the transfer mechanism and at least one magnetron sputtering source on the side of the other surface of the board.

8. The plasma processing apparatus as claimed in claim 7, wherein each of the first magnetron-sputtering film-forming portion and the second magnetron-sputtering film-forming portion has a rotating magnet type magnetron sputtering source.

9. The plasma processing apparatus as claimed in claim 1, wherein the transfer mechanism simultaneously delivers a plurality of the boards.

10. The plasma processing apparatus as claimed in claim 9, wherein the transfer mechanism simultaneously delivers a plurality of the boards in a transfer direction and in a direction perpendicular to the transfer direction.

11. A plasma processing apparatus comprising:
a processing container reducible in pressure;
a first plasma processing portion having a plasma source arranged in the processing container and modifying a surface of a board to be processed, by irradiating the board with a plasma; and
a second plasma processing portion having a plurality of magnetron sputtering sources arranged in the processing container and depositing a thin film by magnetron sputtering,
the plasma source of the first plasma processing portion being disposed so as to allow plasma irradiation on both surfaces of the board without requiring an operation of reversing the board,
the magnetron sputtering sources being disposed to face the both surfaces of the board, respectively, so as to allow formation of thin films on the both surfaces of the board without requiring an operation of reversing the board.

12. The plasma processing apparatus as claimed in claim 11, wherein the first plasma processing portion includes a first plasma excitation electrode and a second plasma excitation electrode which are arranged to face a first surface of the board and a second surface opposite to the first surface, respectively, and to be substantially in parallel to the board and each of which has a size substantially equal to that of the board.

13. The plasma processing apparatus as claimed in claim 12, wherein:
the first plasma processing portion has a mechanism transferring the board in a direction perpendicular to the first surface,
plasma processing of the first surface of the board being performed by bringing the second surface into contact with the second plasma excitation electrode and applying an electric power to the second electrode only or to both of the first and the second electrodes to thereby generate a plasma between the first surface and the first electrode so as to perform plasma processing of the first surface,
plasma processing of the second surface of the board being performed by bringing the first surface into contact with the first plasma excitation electrode and applying an electric power to the first electrode only or to both of the second and the first electrodes to thereby generate a plasma between the second surface and the second electrode so as to perform plasma processing of the second surface.

14. The plasma processing apparatus as claimed in claim 11, comprising a third plasma processing portion arranged in the processing container to be adjacent to the second plasma processing portion and having a plurality of magnetron sputtering sources,
the magnetron sputtering sources being disposed to face the both surfaces of the board, respectively, so as to form a thin film on each of the both surfaces of the board without requiring an operation of reversing the board.

15. The plasma processing apparatus as claimed in claim 11, wherein each of the magnetron sputtering sources is a rotating magnet sputtering source.

16. A printed wiring board manufacturing method using the plasma processing apparatus claimed in claim 11, wherein:
the board is a board to be formed with a wiring pattern on a thermosetting resin;
the method comprising a first plasma processing step of performing, in the first plasma processing portion, plasma excitation by a gas containing at least hydrogen and irradiating the board with active hydrogen to remove an oxide film on at least a part of each of the surfaces of the board; and
a second plasma processing step of performing, in the first plasma processing portion, plasma excitation by a gas containing at least nitrogen and irradiating the board with active nitrogen to nitride at least a part of each of the surfaces of the board.

17. A printed wiring board manufacturing method using the plasma processing apparatus claimed in claim 11, wherein:
the board is a board to be formed with a wiring pattern on a thermosetting resin;
the method comprising a plasma processing step of performing, in the first plasma processing portion, plasma excitation by a gas containing at least hydrogen and nitrogen and irradiating the board with active hydrogen and NH radicals to remove an oxide film on at least a part of each of the surfaces of the board and to simultaneously nitride at least a part of each of the surfaces of the board.

18. A printed wiring board manufacturing method using the plasma processing apparatus claimed in claim 11, wherein:
the board is a board to be formed with a wiring pattern on a thermosetting resin;
the method comprising the steps of:
performing plasma processing of each of the surfaces of the board in the first plasma processing portion; and
forming a conductive layer containing at least one of copper nitride, chromium, aluminum, titanium, and tantalum by the magnetron sputtering sources in the second plasma processing portion.

19. A printed wiring board manufacturing method using the plasma processing apparatus claimed in claim 14, wherein:
the board is a board to be formed with a wiring pattern on a thermosetting resin;
the method comprising the steps of:
performing plasma processing of each of the surfaces of the board in the first plasma processing portion;
forming a first conductive layer by the magnetron sputtering sources in the second plasma processing portion; and
forming a second conductive layer on the first conductive layer by the magnetron sputtering sources in the third plasma processing portion.
